(19) United States
(12) Patent Application Publication
(10) Pub. No.: US 2024/0265165 A1
(43) Pub. Date: Aug. 8, 2024

(54) Method for Extracting Attributes of Starting and Ending Points of Roads in Batches From Urban Regional Road Network

(71) Applicant: Chang'an University, Xi’an (CN)

(72) Inventors: Yuanqing Wang, Xi’an (CN); Yaxiang Li, Xi’an (CN); Yabin Sun, Xi’an (CN); Zhouhao Wu, Xi’an (CN); Minghui Xie, Xi’an (CN); Sen Wei, Xi’an (CN); Shuxin Jin, Xi’an (CN)

(73) Assignee: Chang'an University, Xi’an (CN)

(21) Appl. No.: 18/021,212

(22) PCT Filed: Aug. 5, 2022
(86) PCT No.: PCT/CN2022/110437

§ 371 Date: Feb. 14, 2023

(30) Foreign Application Priority Data
Nov. 4, 2021 (CN) 202111297059.8

(51) Int. Cl. G06F 30/18

(52) U.S. Cl. CPC G06F 30/18

(57) ABSTRACT

A method for extracting attributes of starting and ending points of roads in batches from an urban regional road network: obtaining a line layer Shape file of the urban regional traffic road network, performing topology inspection and correction on the line layer Shape file to be stored as a line layer Shape2 file; processing the line layer Shape2 file to obtain data of a starting point, a turning point, and an ending point of each road to be exported as a point-line layer Shape3 file; intersecting point layer elements and line layer elements of the point-line layer Shape3 file and the line layer Shape2 file to be exported as a point-line layer Shape4 file; processing the point-line layer Shape4 file, exporting a .Csv file; and connecting the line layer Shape2 file with the Csv file to extract the attributes of the starting and ending points of the roads in batches.

### CROSS REFERENCE TO RELATED APPLICATION

This application claims priority to the Chinese Patent Application No. 202111297059.8, filed with the China National Intellectual Property Administration (CNIPA) on Nov. 4, 2021, and entitled “Harmonic Coupling Modeling Method and System for AC/DC Power Network”, which is incorporated herein by reference in its entirety.

### TECHNICAL FIELD

The present disclosure relates to the field of transportation planning, and in particular, to a method for extracting attributes of starting and ending points of roads in batches from an urban regional road network.

### BACKGROUND

Arcgis is a full series of geographic information system (GIS) products representing the highest technical level of GIS successfully launched by Environmental Systems Research Institute, Inc. (ESRI) in the United States after the comprehensive integration of GIS with database, network technology and other mainstream computer technologies. Arcgis is a comprehensive and scalable GIS platform, providing a complete solution for users to build a complete GIS system.

With the development of geographic information technology, GIS technology is widely used in various fields. In transportation planning, the urban regional traffic road network uses the road network system established by Arcgis to match the names of the starting and ending points of the road according to the project requirements, and match corresponding attributes for each section of the roads, in particularly performing the road network matching with high requirements for road naming extraction. When there are a large number of road networks and a large amount of attribute data to be imported, manually matching attributes requires a heavy workload, and it is prone to errors, which requires the use of computer batch operation. In addition, the batch extraction of starting and ending points of the road can be of great help to road naming and road name checking, especially in large and medium-sized cities, where the regional road network is complex, the name distribution is scattered, and manual processing costs manpower and material resources and it is unscientific.

### SUMMARY

In view of the above deficiencies, a method for extracting attributes of starting and ending points of roads in batches from an urban regional road network provided by the present disclosure solves the problems of inaccurate matching and labor and time consumption of manual processing in the prior art.

To achieve the foregoing objective of the present disclosure, the present disclosure adopts the following technical solutions:

A method for extracting attributes of starting and ending points of roads in batches from an urban regional road network comprises the following steps:
S1, obtaining a line layer Shape file of the urban regional traffic road network, and performing topology inspection and correction on the line layer Shape file;
S2, adding an identification (ID) field, and assigning values to the corrected data in sequence with positive integers using the ID field to be stored as a line layer Shape2 file;
S3, loading the line layer Shape2 file into an Arcgis platform, and performing processing to obtain data of starting, turning, and ending points of each road; and assigning points belonging to the same road with an element value of an ID field corresponding to the road to obtain an updated ID field;
S4, adding an ID2 field, arranging data in the line layer Shape2 file according to a descending order of element values in the updated ID field, and assigning values to the repeated elements in the updated ID field in sequence with positive integers using the ID2 field to be exported as a point-line layer Shape3 file;
S5, loading the point-line layer Shape3 file and the line layer Shape2 file into the Arcgis platform, and intersecting point layer elements and line layer elements of the point-line layer Shape3 file and the line layer Shape2 file to obtain intersecting results to be exported as a point-line layer Shape4 file;
S6, loading the point-line layer Shape4 file into the Arcgis platform, arranging data according to the descending order of the element values in the updated ID field and an ascending order of element values in the ID2 field, and adding a new field to calculate the corresponding element values;
S7, saving the processed data to be exported as a .XLS file, and selecting the updated ID field and a corresponding field to be exported as a .Csv file; and
S8, loading the line layer Shape2 file in step S2 into the Arcgis platform, and connecting the line layer Shape2 file with the .Csv file in step S7, so as to extract the attributes of the starting and ending points of the roads in batches from the urban regional road network.

Further, the line layer Shape file in step S1 is a layer file, including road sections. The road sections are line layer elements, including a field identifying number (FID), a road class field Class, a road width field Width, and a name field Name of the traffic road network.

Further, a specific method in step S1 is as follows:
S1-1, obtaining the line layer Shape file of the urban regional traffic road network, loading the line layer Shape file into the Arcgis platform, and establishing a geographic database by using an ArcCatalog tool of the Arcgis platform; and
S1-2, importing a single line layer element of the line layer Shape file, creating a new topology inspection, and connecting the road sections end to end through correction to obtain closed space data, where the correction includes removing road sections which are overlap, intersect, and gap.

Further, a specific method of loading the line layer Shape2 file into an Arcgis platform, and performing processing to obtain data of starting, turning, and ending points of each road in step S3 is as follows:
S3-1, loading the line layer Shape2 file into the Arcgis platform, taking the line layer Shape2 file as input elements using the ArcCatalog tool of the Arcgis platform, and creating a point at starting and ending points of each of the input elements to obtain the data of the starting and ending points of each road, where the input elements include the starting, turning, and ending points; and
S3-2, loading the line layer Shape2 file with the data of the starting and ending points obtained into the Arcgis platform, taking the line layer Shape2 file with the data of the starting and ending points obtained as input elements using the ArcCatalog tool of the Arcgis platform, and creating a point at a turning point of each of the input elements to obtain the data of the turning point of each road.

Further, a specific method of obtain intersecting results in step S5 is as follows:
loading the point-line layer Shape3 file and the line layer Shape2 file into the Arcgis platform, and intersecting the point layer elements and the line layer elements of the point-line layer Shape3 file and the line layer Shape2 file to generate a field Name_1 containing a name of the traffic network.

Further, a specific method of adding a new field to calculate the corresponding element values in step S6 is as follows:
S6-1, adding an ID3 field with the same number of elements as the updated ID field, and in accordance with the name of the traffic network at a certain location in the field Name_1, taking the element value in the updated ID field corresponding to the name of the traffic network at a certain location in the field Name as an element value at the location in the ID3 field;
S6-2, adding a field Rep with the same number of elements as the ID3 field, and determining whether the updated ID field has the same element value with the element value at the same location in the ID3 field, and if yes, setting an element value at a corresponding location in the field Rep to 1; otherwise, setting the element value at the corresponding location in the field Rep to 0;
S6-3, adding a field Acc with the same number of elements as the field Rep, and in the updated data corresponding to a same element value of the updated ID field, if an element value at a certain location in the field Rep is 1, setting an element value at a corresponding location in the field Acc to 0; and if an element value at a certain location in the field Rep is 0, setting an element value at a corresponding location in the field Acc to a number of occurrences that the element value 0 appears in the field Rep up to that location;
S6-4, adding a field Acc_0 with the same number of elements as the field Acc, and in data corresponding to a same element value of the updated ID field, recording a total number of occurrences of the element value 0 in the field Acc in each element of the field Acc_0;
S6-5, adding a field First with the same number of elements as the field Acc, obtaining a location of the element value 1 in the field Acc in data corresponding to a same element value of the updated ID field, and setting an element value of the field First at the location to 1 and remaining element values in the field First to 0; and
S6-6, adding a field End with the same number of elements as the field Acc, obtaining a location where an element value in the field Acc is equal to an element value in the field Acc_0 in data corresponding to a same element value of the updated ID field, and setting an element value in the field End at the location to 1 and remaining element values in the field End to 0.

Further, a specific method of selecting the updated ID field and a corresponding field in step S7 is as follows: selecting a part of the field First whose element is equal to 1 in the field First, and selecting a field Name_1 corresponding to the part of the field First whose element is equal to 1 in the field First and the updated ID field; and selecting part of the field End whose element is equal to 1 in the field End, and selecting a field Name_1 corresponding to the part of the field End whose element is equal to 1 in the field End and the updated ID field.

Further, a specific process of step S8 is as follows:
loading the line layer Shape2 file of step S2 into the Arcgis platform, connecting the line layer Shape2 file with the .Csv file of step S7, and based on element values of the updated ID fields in the line layer Shape2 file and the .Csv file, matching a starting point in the line layer Shape2 file with elements in the field Name_1 corresponding to the field First, and matching an ending point in the line layer Shape2 file with elements in the field Name_1 corresponding to the field End, so as to extract the attributes of the starting and ending points of the roads in batches from the urban regional road network.

The present disclosure has the following beneficial effects:

1. According to the method for extracting attributes of starting and ending points of roads in batches from an urban regional traffic road network, the technical problem that the naming of starting and ending points of roads in the urban regional road network cannot be automatically extracted is solved.

2. The method can greatly reduce the error rate of manual data processing and the time of manual judgment. The method has high efficiency and excellent user experience.

3. The method can extract the attributes of the starting and ending points of the roads in batches from the urban regional traffic road network, which has important significance for urban traffic road network planning.

### BRIEF DESCRIPTION OF THE DRAWINGS

FIG. 1 is a flow chart of the present disclosure.

### DETAILED DESCRIPTION OF THE EMBODIMENTS

The specific implementations of the present disclosure are described below to facilitate those skilled in the art to understand the present disclosure, but it should be clear that the present disclosure is not limited to the scope of the specific implementations. Various obvious changes made by those of ordinary skill in the art within the spirit and scope of the present disclosure defined and determined by the appended claims should fall within the protection scope of the present disclosure.

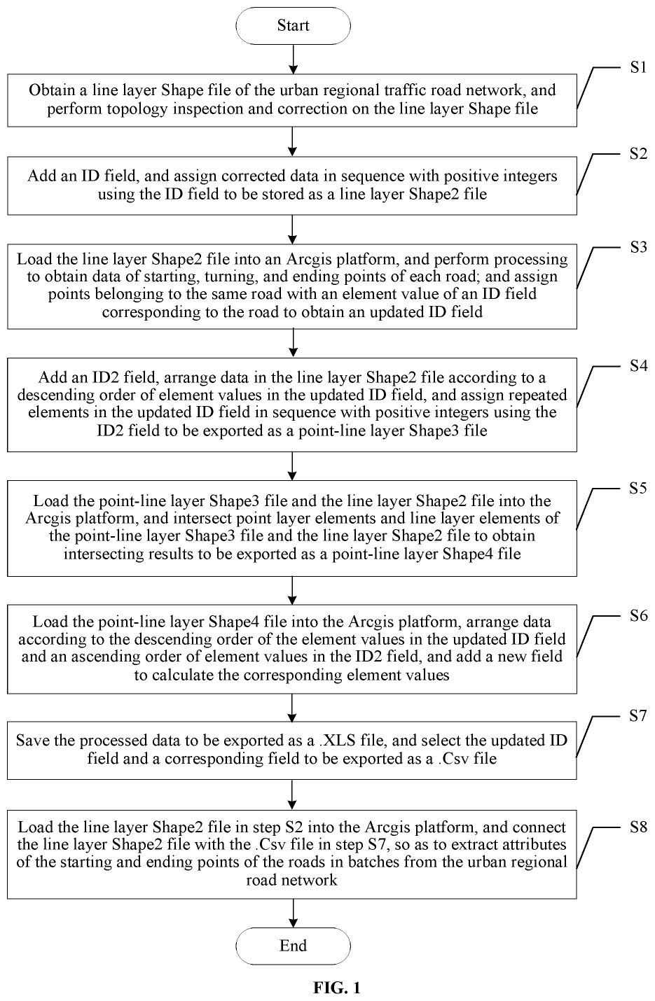

As shown in FIG. 1, a method for extracting attributes of starting and ending points of roads in batches from an urban regional road network includes the following steps.

S1, A line layer Shape file of the urban regional traffic road network is obtained, and topology inspection and correction are performed on the line layer Shape file.

S2, An ID field is added, and corrected data is assigned in sequence with positive integers using the ID field to be stored as a line layer Shape2 file.

S3, The line layer Shape2 file is loaded into an Arcgis platform, and processing is performed to obtain data of starting, turning, and ending points of each road. Points belonging to the same road are assigned with an element value of an ID field corresponding to the road to obtain an updated ID field.

S4, An ID2 field is added, data in the line layer Shape2 file is arranged according to a descending order of element values in the updated ID field, and repeated elements in the updated ID field are assigned in sequence with positive integers using the ID2 field to be exported as a point-line layer Shape3 file.

S5, The point-line layer Shape3 file and the line layer Shape2 file are loaded into the Arcgis platform, and point layer elements and line layer elements of the point-line layer Shape3 file and the line layer Shape2 file are intersected to obtain intersecting results to be exported as a point-line layer Shape4 file.

S6, The point-line layer Shape4 file is loaded into the Arcgis platform, data is arranged according to the descending order of the element values in the updated ID field and an ascending order of element values in the ID2 field, and a new field is added to calculate the corresponding element values.

S7, The processed data is saved to be exported as a .XLS file, and the updated ID field and a corresponding field are selected to be exported as a .Csv file.

S8, The line layer Shape2 file in step S2 is loaded into the Arcgis platform, and the line layer Shape2 file is connected with the .Csv file in step S7, so as to extract the attributes of the starting and ending points of the roads in batches from the urban regional road network.

The line layer Shape file in step S1 is a layer file, including road sections. The road sections are line layer elements, including a FID, a road class field Class, a road width field Width, and a name field Name of the traffic road network.

A specific method in step S1 is as follows.

S1-1, The line layer Shape file of the urban regional traffic road network is obtained, the line layer Shape file is loaded into the Arcgis platform, and a geographic database is established using an ArcCatalog tool of the Arcgis platform.

S1-2, A single line layer element of the line layer Shape file is imported, a new topology inspection is created, and the road sections are connected end to end through correction to obtain closed space data. The correction includes removing road sections which overlap, intersect, and gap.

A specific method of loading the line layer Shape2 file into an Arcgis platform, and performing processing to obtain data of starting, turning, and ending points of each road in step S3 is as follows.

S3-1, The line layer Shape2 file is loaded into the Arcgis platform, the line layer Shape2 file is taken as input elements using the ArcCatalog tool of the Arcgis platform, and a point is created at starting and ending points of each of the input elements to obtain the data of the starting and ending points of each road. The input elements include the starting, turning, and ending points.

S3-2, The line layer Shape2 file with the data of the starting and ending points obtained is loaded into the Arcgis platform, the line layer Shape2 file with the data of the starting and ending points obtained is taken as input elements using the ArcCatalog tool of the Arcgis platform, and a point is created at a turning point of each of the input elements to obtain the data of the turning point of each road.

A specific method of obtain intersecting results in step S5 is as follows.

The point-line layer Shape3 file and the line layer Shape2 file are loaded into the Arcgis platform, and the point layer elements and the line layer elements of the point-line layer Shape3 file and the line layer Shape2 file are intersected to generate a field Name_1 containing a name of the traffic network.

A specific method of adding a new field to calculate the corresponding element values in step S6 is as follows.

S6-1, An ID3 field with the same number of elements as the updated ID field is added, and in accordance with the name of the traffic network at a certain location in the field Name_1, the element value in the updated ID field corresponding to the name of the traffic network at a certain location in the field Name is taken as an element value at the location in the ID3 field.

S6-2, A field Rep with the same number of elements as the ID3 field is added, and whether the updated ID field has the same element value with the element value at the same location in the ID3 field is determined. If yes, an element value at a corresponding location in the field Rep is set to 1. Otherwise, the element value at the corresponding location in the field Rep is set to 0.

S6-3, A field Acc with the same number of elements as the field Rep is added. In the updated data corresponding to a same element value of the updated ID field, if an element value at a certain location in the field Rep is 1, an element value at a corresponding location in the field Acc is set to 0. If an element value at a certain location in the field Rep is 0, an element value at a corresponding location in the field Acc is set to a number of occurrences that the element value 0 appears in the field Rep up to that location.

S6-4, A field Acc_0 with the same number of elements as the field Acc is added. In data corresponding to a same element value of the updated ID field, a total number of occurrences of the element value 0 in the field Acc is recorded in each element of the field Acc_0.

S6-5, A field First with the same number of elements as the field Acc is added. A location of the element value 1 in the field Acc is obtained in data corresponding to a same element value of the updated ID field, and an element value of the field First at the location is set to 1 and remaining element values in the field First to 0.

S6-6, A field End with the same number of elements as the field Acc is added. A location where an element value in the field Acc is equal to an element value in the field Acc 0 is obtained in data corresponding to a same element value of the updated ID field, and an element value in the field End at the location is set to 1 and remaining element values in the field End to 0.

A specific method of selecting the updated ID field and a corresponding field in step S7 is as follows: part of the field First whose element is equal to 1 in the field First is selected, and a field Name_1 corresponding to the part of the field First whose element is equal to 1 in the field First and the updated ID field are selected. Part of the field End whose element is equal to 1 in the field End is selected, and a field Name_1 corresponding to the part of the field End whose element is equal to 1 in the field End and the updated ID field are selected.

A specific process of step S8 is as follows.

The line layer Shape2 file of step S2 is loaded into the Arcgis platform. The line layer Shape2 file is connected with the .Csv file of step S7. Based on element values of the updated ID fields in the line layer Shape2 file and the .Csv file, a starting point in the line layer Shape2 file is matched with elements in the field Name_1 corresponding to the field First, and an ending point in the line layer Shape2 file is matched with elements in the field Name_1 corresponding to the field End, so as to extract the attributes of the starting and ending points of the roads in batches from the urban regional road network.

In an embodiment of the present disclosure:

As shown in Table 1, the ID field assignment results of step S2 are as follows.

TABLE 1

| FID | Class | Width | Name | ID |
|---|---|---|---|---|
| 0 | Main road | 60 | Jincheng Road | 1 |
| 1 | Secondary trunk road | 40 | Qiaohe Road | 2 |
| 2 | Main road | 40 | Haoxiang Road | 3 |

As shown in Table 2, the elements in the ID field after step S3 are repeated (the line elements become point elements), and the ID2 field assignment results of step S4 are as follows (Jincheng Road, Qiaohe Road, and Haoxiang Road in the table are not exhaustive, for example, Jincheng Road currently has more than three “points”).

TABLE 2

| FID | Class | Width | Name | ID | ID2 |
|---|---|---|---|---|---|
| 0 | Main road | 60 | Jincheng Road | 1 | 1 |
| 1 | Main road | 60 | Jincheng Road | 1 | 2 |
| 2 | Main road | 60 | Jincheng Road | 1 | 3 |
| — | — | — | — | — | — |
| 1168 | Secondary trunk road | 40 | Qiaohe Road | 2 | 1 |
| 1169 | Secondary trunk road | 40 | Qiaohe Road | 2 | 2 |
| — | — | — | — | — | — |
| 2356 | Main road | 40 | Haoxiang Road | 3 | 1 |
| 2357 | Main road | 40 | Haoxiang Road | 3 | 2 |

As shown in Table 3, the elements in the ID2 field after step S5 are repeated, and the contents of each field after step S6 are as follows.

TABLE 3

| FID | Class | Width | Name | ID | ID2 | Name_1 | ID3 | Rep | Acc | Acc_0 | First | End |
|---|---|---|---|---|---|---|---|---|---|---|---|---|
| 695 | Main | 60 | Jincheng | 1 | 30 | Haoye | 104 | 0 | 1 | 11 | 1 | 0 |
| | road | | Road | | | Road | | | | | | |
| 804 | Main | 60 | Jincheng | 1 | 29 | Jincheng | 1 | 1 | 0 | 11 | 0 | 0 |
| | road | | Road | | | Road | | | | | | |
| — | — | — | — | — | — | — | — | — | — | — | — | — |
| 2686 | Main | 60 | Jincheng | 1 | 2 | Changfu | 96 | 0 | 9 | 11 | 0 | 0 |
| | road | | Road | | | Road | | | | | | |
| 3022 | Main | 60 | Jincheng | 1 | 1 | Jincheng | 1 | 1 | 0 | 11 | 0 | 0 |
| | road | | Road | | | Road | | | | | | |
| 3023 | Main | 60 | Jincheng | 1 | 1 | Shafu | 10 | 0 | 10 | 11 | 0 | 0 |
| | road | | Road | | | Road | | | | | | |
| 3024 | Main | 60 | Jincheng | 1 | 1 | Jincheng | 97 | 0 | 11 | 11 | 0 | 1 |
| | road | | Road | | | Avenue | | | | | | |

Taking Jincheng Road as an example, after step S6, the element 1 in the field First and the element 1 in the field End as well as the corresponding field Name_1 and ID field are selected, and saved as a .Csv file. Then, in the .Csv file:
ID:1, Name_1: Haoye Road, First: 1, and End: 0, and
ID:1, Name_1: Jincheng Avenue, First: 0, and End: 1.

The .Csv file is matched with the data in the line layer Shape2 file. If the ID element value in the Shape2 file is equal to the ID element value in the .Csv file, such as 1, the starting point of Jincheng Road in the Shape2 file is Haoye Road and the ending point is Jincheng Avenue, so as to extract starting and ending points in the file by computer in batches.

A location of element 1 in the field First is used to represent the starting point of the road, and a location of element 1 in the field End is used to represent the ending point of the road. All the above tables are not exhaustive because the data is too long. The field Name_1 and field Name both process the data of a road network, and contain the same road section information (a road class field Class, a road width field Width, and a name field Name of the traffic road network). That is, if the field Name_1 includes Haoye Road, the field Name shall include Haoye Road. If the field Name includes Haomao Road, the field Name_1 shall include Haomao Road.

According to the method for extracting attributes of starting and ending points of roads in batches from an urban regional traffic road network, the technical problem that the naming of starting and ending points of roads in the urban regional road network cannot be automatically extracted is solved. The method can greatly reduce the error rate of manual data processing and the time of manual judgment. The method has high efficiency and excellent user experience. The method can extract the attributes of the starting and ending points of the roads in batches from the urban regional traffic road network, which has important significance for urban traffic road network planning

What is claimed is:

1. A method for extracting attributes of starting and ending points of roads in batches from an urban regional road network, comprising the following steps:
S1, obtaining a line layer Shape file of the urban regional traffic road network, and performing topology inspection and correction on the line layer Shape file;
S2, adding an identification (ID) field, and assigning values to the corrected data in sequence with positive integers using the ID field to be stored as a line layer Shape2 file;
S3, loading the line layer Shape2 file into an Arcgis platform, and performing processing to obtain data of starting, turning, and ending points of each road; and assigning points belonging to the same road with an element value of an ID field corresponding to the road to obtain an updated ID field;
S4, adding an ID2 field, arranging data in the line layer Shape2 file according to a descending order of element values in the updated ID field, and assigning values to the repeated elements in the updated ID field in sequence with positive integers using the ID2 field to be exported as a point-line layer Shape3 file;
S5, loading the point-line layer Shape3 file and the line layer Shape2 file into the Arcgis platform, and intersecting point layer elements and line layer elements of the point-line layer Shape3 file and the line layer Shape2 file to obtain intersecting results to be exported as a point-line layer Shape4 file;
S6, loading the point-line layer Shape4 file into the Arcgis platform, arranging data according to the descending order of the element values in the updated ID field and an ascending order of element values in the ID2 field, and adding a new field to calculate the corresponding element values;
S7, saving the processed data to be exported as a .XLS file, and selecting the updated ID field and a corresponding field to be exported as a .Csv file;
S8, loading the line layer Shape2 file in step S2 into the Arcgis platform, and connecting the line layer Shape2 file with the .Csv file in step S7, so as to extract the attributes of the starting and ending points of the roads in batches from the urban regional road network.

2. The method for extracting attributes of starting and ending points of roads in batches from an urban regional road network according to claim 1, wherein the line layer Shape file in step S1 is a layer file, comprising road sections; and the road sections are line layer elements, comprising a field identifying number (FID), a road class field Class, a road width field Width, and a name field Name of the traffic road network.

3. The method for extracting attributes of starting and ending points of roads in batches from an urban regional road network according to claim 2, wherein a specific method in step S1 is as follows:
S1-1, obtaining the line layer Shape file of the urban regional traffic road network, loading the line layer Shape file into the Arcgis platform, and establishing a geographic database using an ArcCatalog tool of the Arcgis platform; and
S1-2, importing a single line layer element of the line layer Shape file, creating a new topology inspection, and connecting the road sections end to end through correction to obtain closed space data, wherein the correction comprises removing road sections which are overlap, intersect, and gap.

4. The method for extracting attributes of starting and ending points of roads in batches from an urban regional road network according to claim 1, wherein a specific method of loading the line layer Shape2 file into an Arcgis platform, and performing processing to obtain data of starting, turning, and ending points of each road in step S3 is as follows:
S3-1, loading the line layer Shape2 file into the Arcgis platform, taking the line layer Shape2 file as input elements using the ArcCatalog tool of the Arcgis platform, and creating a point at starting and ending points of each of the input elements to obtain the data of the starting and ending points of each road, wherein the input elements comprise the starting, turning, and ending points; and
S3-2, loading the line layer Shape2 file with the data of the starting and ending points obtained into the Arcgis platform, taking the line layer Shape2 file with the data of the starting and ending points obtained as input elements using the ArcCatalog tool of the Arcgis platform, and creating a point at a turning point of each of the input elements to obtain the data of the turning point of each road.

5. The method for extracting attributes of starting and ending points of roads in batches from an urban regional road network according to claim 2, wherein a specific method of obtain intersecting results in step S5 is as follows:
loading the point-line layer Shape3 file and the line layer Shape2 file into the Arcgis platform, and intersecting the point layer elements and the line layer elements of the point-line layer Shape3 file and the line layer Shape2 file to generate a field Name_1 containing a name of the traffic network.

6. The method for extracting attributes of starting and ending points of roads in batches from an urban regional road network according to claim 5, wherein a specific method of adding a new field to calculate the corresponding element values in step S6 is as follows:
S6-1, adding an ID3 field with the same number of elements as the updated ID field, and in accordance with the name of the traffic network at a certain location in the field Name_1, taking the element value in the updated ID field corresponding to the name of the traffic network at a certain location in the field Name as an element value at the location in the ID3 field;
S6-2, adding a field Rep with the same number of elements as the ID3 field, and determining whether the updated ID field has the same element value with the element value at the same location in the ID3 field, and if yes, setting an element value at a corresponding location in the field Rep to 1; otherwise, setting the element value at the corresponding location in the field Rep to 0;
S6-3, adding a field Acc with the same number of elements as the field Rep, and in the updated data corresponding to a same element value of the updated ID field, if an element value at a certain location in the field Rep is 1, setting an element value at a corresponding location in the field Acc to 0; and if an element value at a certain location in the field Rep is 0, setting an element value at a corresponding location in the field Acc to a number of occurrences that the element value 0 appears in the field Rep up to that location;
S6-4, adding a field Acc_0 with the same number of elements as the field Acc, and in data corresponding to a same element value of the updated ID field, recording a total number of occurrences of the element value 0 in the field Acc in each element of the field Acc_0;
S6-5, adding a field First with the same number of elements as the field Acc, obtaining a location of the element value 1 in the field Acc in data corresponding to a same element value of the updated ID field, and setting an element value of the field First at the location to 1 and remaining element values in the field First to 0; and
S6-6, adding a field End with the same number of elements as the field Acc, obtaining a location where an element value in the field Acc is equal to an element value in the field Acc 0 in data corresponding to a same element value of the updated ID field, and setting an element value in the field End at the location to 1 and remaining element values in the field End to 0.

7. The method for extracting attributes of starting and ending points of roads in batches from an urban regional road network according to claim 6, wherein a specific method of selecting the updated ID field and a corresponding field in step S7 is as follows: selecting part of the field First whose element is equal to 1 in the field First, and selecting a field Name_1 corresponding to the part of the field First whose element is equal to 1 in the field First and the updated ID field; and selecting part of the field End whose element is equal to 1 in the field End, and selecting a field Name_1 corresponding to the part of the field End whose element is equal to 1 in the field End and the updated ID field.

8. The method for extracting attributes of starting and ending points of roads in batches from an urban regional road network according to claim 7, wherein a specific process of step S8 is as follows:
loading the line layer Shape2 file of step S2 into the Arcgis platform, connecting the line layer Shape2 file with the .Csv file of step S7, and based on element values of the updated ID fields in the line layer Shape2 file and the .Csv file, matching a starting point in the line layer Shape2 file with elements in the field Name_1 corresponding to the field First, and matching an ending point in the line layer Shape2 file with elements in the field Name_1 corresponding to the field End, so as to extract the attributes of the starting and ending points of the roads in batches from the urban regional road network.
